(19) United States
(12) Patent Application Publication
(10) Pub. No.: US 2014/0342484 A1
(43) Pub. Date: Nov. 20, 2014

(54) METHOD FOR PRODUCING AN OPTOELECTRONIC SEMICONDUCTOR CHIP AND CORRESPONDING OPTOELECTRONIC SEMICONDUCTOR CHIP

(71) Applicants: Joachim Hertkorn, Alteglofsheim (DE); Karl Engl, Pentling (DE); Berthold Hahn, Hemau (DE); Andreas Weimar, Regensburg (DE); Peter Stauss, Regensburg (DE)

(72) Inventors: Joachim Hertkorn, Alteglofsheim (DE); Karl Engl, Pentling (DE); Berthold Hahn, Hemau (DE); Andreas Weimar, Regensburg (DE); Peter Stauss, Regensburg (DE)

(73) Assignee: OSRAM Opto Semiconductors GmbH, Regensburg (DE)

(21) Appl. No.: 14/344,825

(22) PCT Filed: Aug. 28, 2012
(86) PCT No.: PCT/EP2012/066699

§ 371 Date: Jul. 16, 2014

(30) Foreign Application Priority Data
Sep. 30, 2011 (DE) 10 2011 114 670.2

(51) Int. Cl. H01L 33/00

(52) U.S. Cl. CPC H01L 33/007; H01L 2933/0025
USPC 438/46

(57) ABSTRACT

A method of producing a semiconductor chip includes providing a silicon growth substrate, producing a III nitride buffer layer on the growth substrate by sputtering, and growing a III nitride semiconductor layer sequence having an active layer above the buffer layer.

### TECHNICAL FIELD

This disclosure relates to a method of producing an optoelectronic semiconductor chip and an optoelectronic semiconductor chip.

### BACKGROUND

Dadgar et al., Applied Physics Letters, Vol. 80, No. 20, from May 20, 2002, discloses a method of producing blue-emitting light-emitting diodes on silicon.

There is in any event a need for a method of efficiently producing an optoelectronic semiconductor chip.

### SUMMARY

We provide a method of producing a semiconductor chip including providing a silicon growth substrate, producing a III nitride buffer layer on the growth substrate by sputtering, and growing a III nitride semiconductor layer sequence having an active layer above the buffer layer.

We also provide a method of producing a semiconductor chip including providing a silicon growth substrate, producing a III nitride buffer layer on the growth substrate by sputtering, and growing a III nitride semiconductor layer sequence having an active layer above the buffer layer, wherein the buffer layer is based on AlN and applied directly to the growth substrate, oxygen is admixed with the buffer layer, and a proportion of oxygen in the buffer layer decreases monotonically in a direction away from the growth substrate.

### BRIEF DESCRIPTION OF THE DRAWINGS

FIG. 1 shows a schematic illustration of an example of a method described to produce an optoelectronic semiconductor chip.

FIGS. 2 to 5 show schematic sectional illustrations of examples of optoelectronic semiconductor chips.

### DETAILED DESCRIPTION

Our method may comprise providing a growth substrate. The growth substrate is preferably a silicon substrate. A surface adapted for the growth is preferably an Si-111 surface. The surface provided for the growth can be particularly smooth and have a roughness of at most 10 nm. A thickness of the growth substrate is preferably at least 50 μm or at least 200 μm.

The method may comprise producing a III nitride buffer layer on the growth substrate. The buffer layer is produced by sputtering. In other words, the buffer layer is not produced by vapor phase epitaxy such as metal organic chemical vapor phase epitaxy, MOVPE for short.

A III nitride semiconductor layer sequence having an active layer may be grown above the buffer layer. The active layer of the semiconductor layer sequence generates electromagnetic radiation, in particular, in the ultraviolet or visible spectral range during\ operation of the semiconductor chip. In particular, a wavelength of the generated radiation is 430 nm to 680 nm. The active layer preferably comprises one or a plurality of pn junctions or one or a plurality of quantum well structures.

The semiconductor material is preferably a nitride compound semiconductor material such as AlₙIn₁₋ₙ₋ₘGaₘN where 0≦n≦1, 0≦m≦1 and n+m≦1. In this case, the semiconductor layer sequence can comprise dopants and additional constituents. For the sake of simplicity, however, only the essential constituents of the crystal lattice of the semiconductor layer sequence, that is to say Al, Ga, In and N, are specified, even if these can be replaced and/or supplemented in part by small amounts of further substances.

The following equations may apply: 0≦n≦0.2 and/or 0.35≦m≦0.95 and/or 0<1-n m≦0.5, The stated ranges of values for n and in preferably hold true for all sublayers of the semiconductor layer sequence, dopants not being included. It is possible in this case, however, for the semiconductor layer sequence to have one or a plurality of central layers for which a departure is made from the stated values for n, m and instead it holds true that 0.75≦n≦1 or 0.80≦n≦1.

The method may produce an optoelectronic semiconductor chip, in particular a light-emitting diode. The method comprises at least the following steps, preferably in the order indicated:

providing a silicon growth substrate,

producing a III nitride buffer layer on the growth substrate by means of sputtering, and

growing a III nitride semiconductor layer sequence having an active layer onto or above the buffer layer.

In contrast to MOVPE, thick layers can be produced comparatively cost-effectively and with relatively high growth rates by sputtering. In this regard, by way of example, layers composed, for instance, of AlN and having a thickness of up to 1 μm can be deposited within a few minutes.

Furthermore, the installation in which sputtering is carried out can be free of gallium. In an epitaxy installation for MOVPE, gallium is typically present as an impurity since gallium-containing layers are required specifically for light-emitting diodes that emit in the blue spectral range. As a result of gallium impurities in conjunction with silicon substrates, however, so-called “meltback” can arise. Meltback denotes a brownish, relatively soft compound composed of gallium and silicon. By virtue of the gallium, silicon is released from the growth substrate and this results in efflorescence and holes at a surface of the silicon substrate provided for the growth. This can lead to poorer growth results.

Furthermore, as a result of the buffer layer being produced by sputtering, the subsequent MOVPE process can be shortened and/or simplified. In particular, it is possible to dispense with a nucleation layer directly on the substrate and apply the buffer layer directly to the growth substrate.

Moreover, it is possible, as a result of the sputtering of the buffer layer, to reduce the use of aluminum in the MOVPE process of producing the semiconductor layer sequence. Graphite holders are typically used as substrate holders on account of the high temperatures in the MOVPE process. The graphite holder can be covered by a thin, whitish layer comprising aluminum and/or comprising gallium in the MOVPE, as a result of which a thermal radiation behavior and a heating behavior of the graphite holder are altered. As a result of the buffer layer being produced by means of sputtering, outside a vapor phase epitaxy reactor, the covering of the graphite holder with aluminum is significantly reduced and parameters for the MOVPE process can be set more easily.

The buffer layer may be deposited in a multilayered fashion. For example, a first sublayer of the buffer layer, the first sublayer being situated closest to the growth substrate, is formed by a thin aluminum layer. The thickness of the aluminum layer is, for example, one, two or three atomic monolayers. Preferably, the aluminum layer is free or substantially free of nitrogen such that the growth substrate does not come directly into contact with nitrogen at the growth area.

The buffer layer may comprise a second sublayer composed of AlN, which is deposited more slowly than a succeeding third sublayer comprised of AlN. The second and third sublayers preferably directly succeed one another and furthermore preferably directly succeed the first sublayer. In particular, the buffer layer consists of three such sublayers.

Oxygen may be admixed with the buffer layer during sputtering. A proportion by weight of the oxygen in the buffer layer, which is based on aluminum nitride, in particular, is preferably at least 0.1% or at least 0.2% or at least 0.5%. Furthermore, the proportion by weight of the oxygen in the buffer layer is preferably at most 10% or at most 5% or at most 1.5%. Introduction of oxygen in the buffer layers is also specified in DE 100 34 263 B4, the subject matter of which is incorporated herein by reference.

The proportion of oxygen in the buffer layer may be reduced monotonically or strictly monotonically in a direction away from the growth substrate. In particular, a highest oxygen concentration is present in a thin layer having a thickness of 10 nm to 30 nm directly at the silicon growth substrate. The oxygen content can decrease in a stepped manner or linearly in a direction away from the growth substrate.

The buffer layer may be grown with a thickness of at least 10 nm or of at least 30 nm or of at least 50 nm. Alternatively or additionally, the thickness of the buffer layer is at most 1000 nm or at most 200 nm or at most 150 nm. In particular, the thickness of the buffer layer is approximately 100 nm.

An intermediate layer may be applied directly to the buffer layer. The intermediate layer is applied by sputtering or a vapor phase epitaxy such as MOVPE. The intermediate layer is preferably based on AlGaN.

The intermediate layer may be grown such that the aluminum content decreases in a direction away from the growth substrate, monotonically or strictly monotonically, that is to say, for example, in a stepped manner or linearly.

The intermediate layer may be grown with a plurality of plies. In individual plies of the intermediate layer, the aluminum content is preferably constant or approximately constant. The individual plies preferably have thicknesses of 20 nm to 100 nm, in particular approximately 50 nm. The intermediate layer comprises, in particular, two plies to six plies, preferably four plies. A total thickness of the intermediate layer is, for example, 50 nm to 500 nm or 100 nm to 300 nm, preferably approximately 200 nm.

A growth layer may be grown in particular directly onto the intermediate layer. The growth layer is preferably a doped or else an undoped GaN layer. The thickness of the growth layer is preferably 50 nm to 300 nm. The growth layer is preferably produced by sputtering or by MOVPE.

A masking layer may be applied in particular directly to the growth layer. The masking layer is formed, for example, from a silicon nitride, a silicon oxide, a silicon oxynitride or from boron nitride or magnesium oxide. The thickness of the masking layer is preferably at most 2 nm or at most 1 nm or at most 0.5 nm. In particular, the masking layer is produced with a thickness amounting on average to one or two monolayers. The masking layer can be produced by sputtering or by MOVPE.

The masking layer may be applied to the underlying layer with a degree of coverage of at least 20% or of at least 50% or of at least 55%. Preferably, the degree of coverage is at most 90% or at most 80% or at most 70%. In other words, the growth substrate and/or the growth layer, as seen in plan view, is then covered by a material of the masking layer to the extent of the proportions mentioned. Therefore, the growth layer is then exposed in places.

A coalescence layer may be grown, in particular directly onto the masking layer and onto the growth layer exposed in places. The coalescence layer is preferably based on undoped or substantially undoped GaN. The coalescence layer grows on the growth layer exposed in places, and thus in openings of the masking layer. Proceeding from the openings in the masking layer, the coalescence layer coalesces to form a closed layer having comparatively few defects.

The coalescence layer may be grown with a thickness of at least 300 nm or of at least 400 nm. Alternatively or additionally, the thickness is at most 3 μm or at most 1.2 μm.

A central layer may be grown onto the coalescence layer, in particular, in direct physical contact. The central layer is preferably an AlGaN layer having an aluminum content of 75% to 100% or an AlN layer. The thickness of the central layer is preferably 5 nm to 50 nm, in particular 10 nm to 20 nm. The central layer may be doped.

A plurality of central layers may be grown, wherein the central layers can each be formed identically within the scope of the production tolerances. A respective GaN layer, which can be doped or undoped, is preferably situated between two adjacent central layers. The GaN layer is furthermore preferably in direct contact with the two adjacent central layers. The thickness of the GaN layer is then preferably at least 20 nm or at least 50 nm or at least 500 nm and can alternatively or additionally be at most 1000 nm or at most 2000 nm or at most 3000 nm.

The semiconductor layer sequence having the active layer may be grown onto the central layer or one of the central layers situated furthest away from the growth substrate. The semiconductor layer sequence is preferably in direct contact with the central layer and is based on AlInGaN or on InGaN. A layer of the semiconductor layer sequence which adjoins the central layer is preferably n-doped. An n-doping is effected, for example, with silicon and/or with germanium.

A temperature of 550° C. to 900° C. is present during the sputtering of the buffer layer and/or of the growth layer and/or of the masking layer. A pressure during sputtering is furthermore in particular 10⁻³ mbar to 10⁻² mbar.

The growth rate during the sputtering of the buffer layer or of the other layers produced by sputtering is at least 0.03 nm/s and/or at most 0.5 nm/s. The sputtering is preferably carried out under an atmosphere comprising argon and nitrogen. A ratio of argon to nitrogen is preferably 1:2, with a tolerance of at most 15% or of at most 10%.

A carrier substrate may be fitted to a side of the semiconductor layer sequence situated opposite the growth substrate. The growth substrate is subsequently removed, for example, by a laser lift-off technique or by etching. Further layers, in particular mirror layers, electrical contact layers and/or connecting means layers such as solders, can be situated between the semiconductor layer sequence and the carrier substrate.

The buffer layer may be produced in a sputtering deposition installation and the semiconductor layer sequence is grown in a vapor phase epitaxy reactor different therefrom. Particularly preferably, the sputtering deposition installation is free of gallium and/or free of graphite.

An optoelectronic semiconductor chip is furthermore disclosed. The optoelectronic semiconductor chip can be produced by a method as specified in one or more of the examples described above. Features of the method are therefore also disclosed for the optoelectronic semiconductor chip, and vice versa.

The optoelectronic semiconductor chip may comprise a semiconductor layer sequence having an active layer that generates radiation. The semiconductor layer sequence furthermore comprises at least one n-doped layer and at least one p-doped layer, wherein these doped layers preferably directly adjoin the active layer. The semiconductor layer sequence is based on AlInGaN or on InGaN.

The semiconductor chip comprises a carrier substrate at a p-side of the semiconductor layer sequence. A central layer is situated at a side of the n-doped layer of the semiconductor layer sequence which faces away from the carrier substrate, the central layer being based on AlGaN and having a high aluminum content and being grown with a thickness of 5 nm to 50 nm. A plurality of central layers can be formed, between which gallium nitride layers are situated.

A coalescence layer composed of doped or undoped GaN having a thickness of 300 nm to 1.5 μm is situated at a side of the central layer or of one of the central layers which faces away from the carrier substrate. Furthermore, the semiconductor chip is provided with a roughening that extends from the coalescence layer as far as or into the n-doped layer of the semiconductor layer sequence. A radiation exit area of the semiconductor layer sequence is formed partly by the coalescence layer. The or at least one of the central layers is exposed in places by the roughening.

The method described here and the semiconductor chip described here are explained in greater detail below on the basis of examples with reference to the drawings. In this case, identical reference signs indicate identical elements in the individual figures. In this case, however, relations to scale are not illustrated. Rather, individual elements may be illustrated with exaggerated size in order to afford a better understanding.

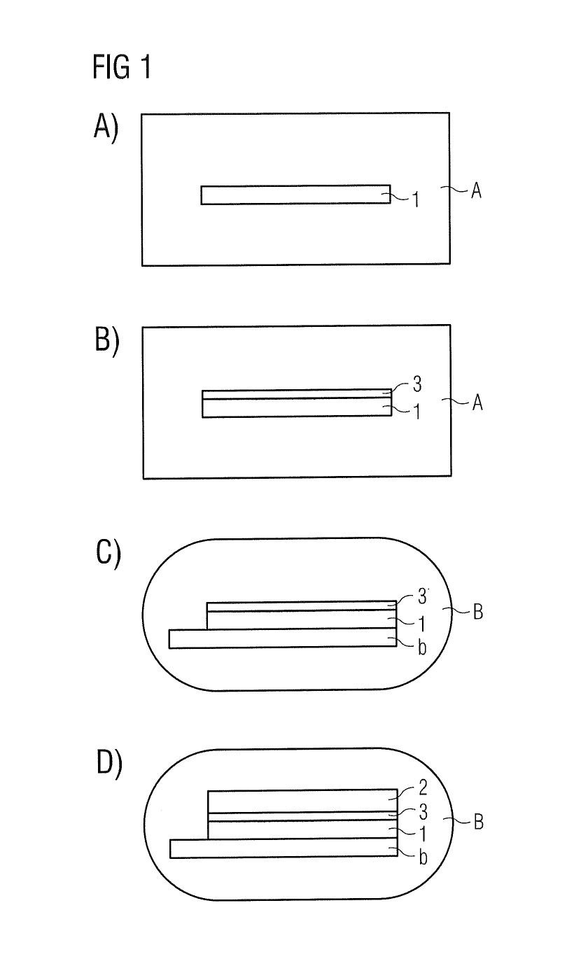

FIG. 1 schematically illustrates a method of producing an optoelectronic semiconductor chip 10. In accordance with FIG. 1A, a silicon growth substrate 1 is provided in a sputtering deposition installation A. In the method step in accordance with FIG. 1B, a buffer layer 3 is sputtered onto the growth substrate 1 in the sputtering deposition installation A. The buffer layer 3 is an AlN layer, which is preferably provided with oxygen.

A temperature during the sputtering of the buffer layer 3 is preferably approximately 760° C. The pressure in the sputtering deposition installation A is, in particular, approximately 5×10⁻² mbar, an argon-nitrogen atmosphere being present. The deposition rate during the sputtering of the buffer layer 3 is approximately 0.15 nm/s. The sputtering power is preferably 0.5 kW to 1.5 kW, in particular approximately 0.5 kW. The buffer layer 3 is produced with a thickness of approximately 100 nm. The sputtering deposition installation A is free of gallium.

In the method step in accordance with FIG. 1C, the growth substrate 1 with the buffer layer 3 is transferred from the sputtering deposition installation A into an MOVPE reactor B. The growth substrate 1 is situated on a substrate holder b, which is preferably formed from graphite. By virtue of the fact that the AlN buffer layer 3 is produced in the sputtering deposition installation A, rather than in the MOVPE reactor B, coating of the substrate holder b with a reflective layer comprising aluminum and/or gallium can be prevented or greatly reduced.

To grow a semiconductor layer sequence 2 having an active layer that generates radiation, the growth substrate 1 with the buffer layer 3 remains in the MOVPE reactor B. The semiconductor layer sequence 2 is therefore applied epitaxially to the sputtered buffer layer 3.

Since the growth of the gallium-containing semiconductor layer sequence 2 is effected spatially separately from the production of the buffer layer 3, it is possible to prevent gallium impurities from being situated in the sputtering deposition installation A. This makes it possible for no gallium to come into direct contact with the silicon growth substrate 1 or with a growth area thereof. A so-called “meltback” can be prevented as a result.

The method preferably takes place in the wafer assemblage. Further method steps such as division into individual semiconductor chips 10 or production of additional functional layers are not shown in FIG. 1 to simplify the illustration.

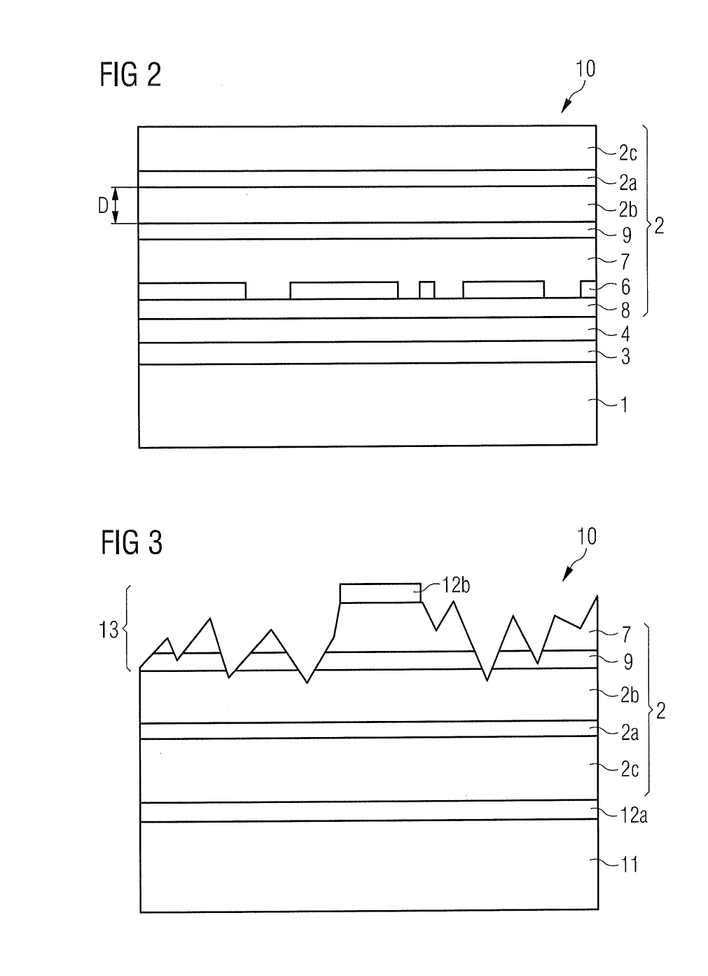

FIG. 2 schematically illustrates one example of the optoelectronic semiconductor chip 10. The sputtered buffer layer 3 is situated on the silicon growth substrate 1. Besides oxygen or as an alternative thereto, the buffer layer 3 can also comprise indium and/or silicon.

The buffer layer 3 is directly followed by an intermediate layer 4. The intermediate layer 4 preferably has a plurality of plies, not depicted in FIG. 2. The plies have, for example, in each case thicknesses of approximately 50 nm and exhibit an aluminum content that decreases in a direction away from the growth substrate 1, wherein the aluminum content of the individual plieAs can be approximately 95%, 60%, 30% and 15%, in particular with a tolerance of at most ten percentage points or of at most five percentage points.

The intermediate layer 4 is followed directly by a growth layer 8 composed of doped or undoped GaN. A thickness of the growth layer 8 is preferably approximately 200 nm. If the growth layer 8 is doped, then a dopant concentration is preferably at least a factor of 2 lower than a dopant concentration of an n-doped layer 2b of the semiconductor layer sequence 2.

In a direction away from the growth substrate 1, the growth layer 8 is succeeded directly by a masking layer 6. The masking layer 6 covers the growth layer 8 preferably to the extent of approximately 60% or to the extent of approximately 70%. The growth layer 8 is formed from a few monolayers of silicon nitride.

In openings of the masking layer 6, a coalescence layer 7 composed of doped or undoped GaN grows at the growth layer 8. In a direction away from the growth substrate 1, the coalescence layer 7 coalesces to form a continuous layer. The coalescence layer 7 is, in particular, thinner than 2 μm or than 1.5 μm. The thickness of the coalescence layer 7 is preferably 0.5 μm to 1.0 μm.

The coalescence layer 7 is succeeded directly by a central layer 9. Preferably, the central layer 9 is an AlGaN layer having a high aluminum content or an AlN layer and having a thickness of approximately 15 nm or of approximately 20 nm.

It is also possible for the central layer 9 to comprise a plurality of sublayers. For example, the coalescence layer 7 is succeeded by a first sublayer composed of AlGaN and the first sublayer is succeeded by a second sublayer composed of AlGaN having a higher Al content. Succeed means preferably along the growth direction and can mean that the layers succeeding one another touch one another.

The central layer 9 is followed by the n-doped layer 2b of the semiconductor layer sequence 2, which adjoins an active layer 2a. At least one p-doped layer 2c is situated at a side of the active layer 2a which faces away from the growth substrate 1. The layers 2a, 2b, 2c of the semiconductor layer sequence 2 are preferably based on InGaN. A dopant concentration of the n-doped layer 2b is preferably 5×10¹⁸/ccm to 1×10²⁰/ccm or 1×10¹⁹/ccm to 6×10¹⁹/ccm. The n-doped layer 2b is preferably doped with germanium and/or with silicon. The p-doped layer 2c is preferably doped with magnesium.

A thickness D of the n-doped layer 2b is, for example, 1.0 μm to 4 μm, in particular 1.5 μm to 2.5 μm. In a region of the n-doped layer 2b that is closest to the central layer 9, wherein this region has a thickness preferably of 100 nm to 500 nm, a dopant concentration is optionally reduced and is in this region, for example, 5×10¹⁷/ccm to 1×10¹⁹/ccm, in particular approximately 1×10¹⁸/ccm. This region is not depicted in the figures.

In the example of the semiconductor chip 10 in accordance with FIG. 3, the growth substrate 1 and also the buffer layer 3 and the intermediate layer 4 are removed, as is also possible in connection with FIG. 2. A first contact layer 12a is fitted to a p-side of the semiconductor layer sequence 2. The semiconductor layer sequence 2 is connected to a carrier substrate 11 via the first contact layer 12a. A thickness of the carrier substrate 11 is preferably 50 μm to 1 mm.

A roughening 13 is produced at a side of the semiconductor layer sequence 2 which faces away from the carrier substrate 11. The roughening 13 extends as far as or into the n-doped layer 2b of the semiconductor layer sequence 2. Therefore, the n-doped layer 2b and the central layer 9 are exposed in places by the roughening. Particularly preferably, the masking layer 6 is completely removed by the roughening 13.

Optionally, a further contact layer 12b is fitted to the side facing away from the carrier substrate, via which further contact layer the semiconductor chip 10 is electrically contact-connectable and energizable, for instance by means of a bonding wire. Further optional layers such as mirror layers or connecting means layers are not depicted in FIG. 3.

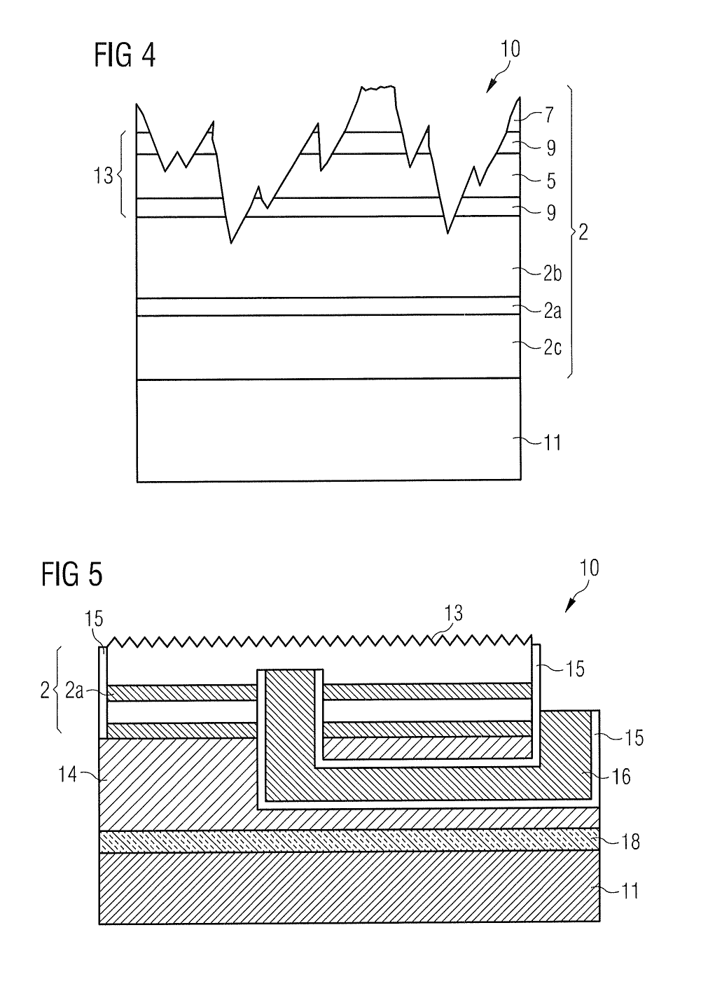

A further example of the semiconductor chip 10 can be seen in FIG. 4. Layers such as contact layers or mirror layers are not illustrated in FIG. 4 to simplify the illustration. The semiconductor chip 10 in accordance with FIG. 4 comprises two central layers 9, between which a GaN layer 5 is situated.

The roughening 13 extends through both central layers 5 right into the n-doped layer 2b. In contrast to the illustration, it is possible for one of the central layers 9 not to be affected by the roughening. Furthermore, it is possible for the central layer 9 closest to the active layer 2a to be an etching stop layer for the production of the roughening 13. In contrast to the illustration in FIG. 4, it is also possible for more than two central layers 9 to be present, which are each constructed identically to one another or differently from one another.

FIG. 5 shows a further example of the semiconductor chip 10. The semiconductor layer sequence 2 is fixed to the carrier substrate 11 via a connector 18, which is a solder, for example. That side of the semiconductor layer sequence 2 facing the carrier substrate 11 is electrically contact-connected via a first electrical connection layer 14 and via the carrier substrate 11.

A side of the semiconductor layer sequence 2 facing away from the carrier substrate 11 is furthermore contact-connected via a second electrical connection layer 16. The second connection layer 16 penetrates through the active layer 2a, as seen from the carrier substrate 11, and is led laterally alongside the semiconductor layer sequence 2. By way of example, the second connection layer 16 can be connected laterally alongside the semiconductor layer sequence 2 to a bonding wire, not depicted.

The roughening 13 does not extend as far as the second connection layer 16. Furthermore, the connection layers 16, 14 are electrically insulated from one another by a separating layer 15, for example composed of silicon oxide or a silicon nitride. The central layer and the coalescence layer are not depicted in FIG. 5. The semiconductor chip 10 can thus be similar to that specified in US 2010/0171135 A1, the subject matter of which is incorporated herein by reference.

Our methods and chips are not restricted by the description on the basis of the examples. Rather, this disclosure encompasses every novel feature and also every combination of features, which in particular includes every combination of features in the appended claims, even if the feature or combination itself is not explicitly specified in the claims or examples.

1.-13. (canceled)

14. A method of producing a semiconductor chip comprising:
providing a silicon growth substrate,
producing a III nitride buffer layer on the growth substrate by sputtering, and
growing a III nitride semiconductor layer sequence having an active layer above the buffer layer.

15. The method according to claim 14, wherein the buffer layer is based on AlN and applied directly to the growth substrate.

16. The method according to claim 15, wherein oxygen is admixed with the buffer layer, and a proportion by weight of the oxygen is 0.1% to 10%.

17. The method according to claim 16, wherein the proportion of oxygen in the buffer layer decreases monotonically in a direction away from the growth substrate.

18. The method according to claim 14, wherein the buffer layer has a thickness of 10 nm to 1000 nm.

19. The method according to claim 14, wherein an intermediate layer is applied directly on the buffer layer by sputtering or vapor phase epitaxy, the intermediate layer is based on AlGaN, and an Al content in the intermediate layer decreases monotonically in a direction away from the growth substrate.

20. The method according to claim 19, wherein the following layers are produced onto the intermediate layer in a manner one directly on top of another and in the order indicated:
a growth layer, based on GaN, produced by sputtering or vapor phase epitaxy,
a masking layer, based on SiN, wherein the masking layer covers the growth layer with a degree of coverage of 50% to 90%, and the masking layer is produced by sputtering or vapor phase epitaxy,
a coalescence layer, based on GaN and grown by vapor phase epitaxy,
one or a plurality of central layers composed of AlGaN and/or composed of AlN, wherein, in the case of a plurality of central layers, a respective GaN layer is grown between two adjacent central layers by vapor phase epitaxy, and the semiconductor layer sequence, based on AlInGaN and grown by vapor phase epitaxy.

21. The method according to claim 14, wherein the sputtering is carried out at a temperature of 550° C. to 900° C. and at a pressure of 1×10⁻³ mbar to 1×10⁻² mbar.

22. The method according to claim 14, wherein a growth rate during the sputtering is 0.03 nm/s to 0.5 nm/s, the sputtering is carried out under an atmosphere comprising Ar and comprising N₂, and a ratio of Ar to N₂ is 1 to 2, with tolerance of at most 15%.

23. The method according to claim 14, wherein a carrier substrate is fitted to a side of the semiconductor layer sequence facing away from the growth substrate, and the growth substrate is subsequently removed.

24. The method according to claim 14, wherein the buffer layer is produced in a sputtering deposition installation (A) and the semiconductor layer sequence is grown in a vapor phase epitaxy reactor (B) different therefrom, and the sputtering deposition installation (A) is free of gallium.

25. The method according to claim 14, wherein the semiconductor chip is an optoelectronic semiconductor chip.

26. A method of producing a semiconductor chip comprising:
providing a silicon growth substrate,
producing a III nitride buffer layer on the growth substrate by sputtering, and
growing a III nitride semiconductor layer sequence having an active layer above the buffer layer, wherein
the buffer layer is based on AlN and applied directly to the growth substrate,
oxygen is admixed with the buffer layer, and
a proportion of oxygen in the buffer layer decreases monotonically in a direction away from the growth substrate.

27. The method according to claim 26, wherein the proportion of oxygen in the buffer layer decreases strictly monotonically in a direction away from the growth substrate.

28. The method according to claim 26, wherein the highest oxygen concentration is present in a thin layer having a thickness of 10 nm to 30 nm directly at the silicon growth substrate.

29. The method according to claim 26, wherein an oxygen content decreases in a stepped manner or linearly in a direction away from the growth substrate.
